(19) United States
(12) Patent Application Publication
(10) Pub. No.: US 2025/0357938 A1
(43) Pub. Date: Nov. 20, 2025

(54) MAGNETO-OPTICALLY CONTROLLED ATOMIC LOCALIZATION UNDER INDUCED GENERATED COHERENCE

(71) Applicant: Abu Dhabi University, Abu Dhabi (AE)

(72) Inventors: Montasir Yousof Abdallah Qasymeh, Abu Dhabi (AE); Nadia Boutabba, Abu Dhabi (AE); Hazrat Ali, Abbotabad (PK); Atta Ur Rahman, Karachi (PK)

(73) Assignee: Abu Dhabi University, Abu Dhabi (AE)

(21) Appl. No.: 18/663,240

(22) Filed: May 14, 2024

(51) Int. Cl. H03L 7/26; G01N 15/0205; G01N 15/0227; G04F 5/14; G06N 10/40

(52) U.S. Cl. CPC H03L 7/26; G01N 15/0227; G04F 5/145; G06N 10/40; G01N 2015/025

(57) ABSTRACT

A method, for atomic localization in a four-level atomic system. The method includes generating a magnetic field and a linearly polarized weak probe field. The magnetic field and the linearly polarized weak probe field are generated by a polarizer. The method also includes generating a strong control field. The method includes applying the magnetic field, the linearly polarized weak probe, and the strong control field to atomic vapors. The method includes generating an SGC effect to the atomic vapors based on an interference created by applying the magnetic field, the linearly polarized weak probe, and the strong control laser field to atomic vapors. The method includes determining atom locations based on generating the SGC effect; and also generating an electronic graph showing the atom locations.

### BACKGROUND

Recent research investigates one of the most fascinating physics studies: the precise localization of an atom; this refers to the process of determining the position or spatial distribution of atoms in a system. Atomic localization research has diverse applications, including laser cooling, neutral atom trapping, atom nano-lithography, and others. In quantum mechanics, finding an atom in a precise localization is tightly related to the concept of diffraction.

A particle's position is described by the probability distribution, which refers to the region in space where an electron is likely to be found near the atomic nucleus. As a result, an atom can be localized by observing diffraction patterns through a crystal lattice or a narrow slit. This means that as electrons move around the atomic nucleus, their wave functions can interfere constructively or destructively, resulting in observable diffraction patterns (due to their wave-like behavior). This is known as the “diffractive scattering”, and it occurs whenever an atom beam interacts with a periodic structure, such as an optical lattice. The atom wave-like diffract and interfere with each other as they pass through the periodic structure, resulting in patterns. These patterns depend on factors like the periodic potential spacing and the angle of incidence of the atomic beam.

Position precision in this context can be achieved in a variety of ways, including measuring the phase change of the standing wave once an atom is subjected to a spontaneous Autler-Townes spectrum, analyzing the population of the upper state or probe absorption, resonance imaging methods, coherent-controlled resonant fields and standing-wave field. To precisely localize atoms, innovative quantum techniques use various detection methods based on quantum interference and atomic coherences. For instance, the optical lattice can be used to precisely localize atoms within individual lattice sites by carefully engineering the lattice potential. Other techniques include quantum imaging, spin squeezing, quantum state tomography, quantum sensing, and others.

One successful experimental technique is based on the atomic interferometry with cold atoms, which converts position information into an intensity spectrum using standing waves. This uses the field's Rabi frequencies to calculate the position-dependent field amplitude. Finally, Resonance fluorescence, long-lived electronic states, light absorption, quadrature phases of light fields interacting with the atom, and combinations of these, have all made substantial advances in pinpointing the exact location of atoms. Although numerous attempts to improve measurement accuracy were developed based on various methods, new various research is ongoing, this includes the use of absorption spectra, amplitude- and phase-dependent emission, dark resonances, coherent population trapping among others. However, all these techniques require sophisticated experimental designs to improve precision, sensitivity, and quantum state preservation.

### BRIEF DESCRIPTION OF DRAWINGS

FIGS. 1A, 1B, 1C are schematic diagrams of the described system for determining atom localization;

FIGS. 2A 2B, 2C, and 2D are diagrams of example graphs;

FIGS. 3A, 3B, 3C, and 3D are diagrams of example graphs;

FIGS. 4A, 4B, 4C, and 4D are a diagrams of example graphs;

FIGS. 5A, 5B, 5C, and 5D are diagrams of example graphs;

FIGS. 6A, 6B, 6C, and 6D are diagrams of example graphs;

FIGS. 7A, 7B, 7C, and 7D are diagrams of example graphs;

FIG. 8 is a diagram of a network environment; and

FIG. 9 is a diagram of an example computing device.

### DETAILED DESCRIPTION OF PREFERRED EMBODIMENTS

The following detailed description refers to the accompanying drawings. The same reference numbers in different drawings may identify the same or similar elements.

Systems, devices, and/or methods described herein may allow for accurate atomic localization in a four-level atomic system by using the left and the right circularly polarized light magneto-optical rotation {“MOR”) effect. In embodiments, the use of a magnetic field induces a spontaneously generated coherence (“SGC”), and dispersive standing wave fields (“DSWFs”) with a phase shift that demonstrates a high precision in localizing the atom. In embodiments, the “MOR” effect allows for a broad and flexible range of atomic control, for instance, the probability of localizing the atom is increased by a factor of 2 when the strength of the magnetic field increases. Furthermore, the dynamics of the atomic localization is fully controllable with phase shift via DSWFs which enables high precision in localizing the atom.

In embodiments, the atomic position is inverted by switching the standing waves from in phase to out phase, resulting in a phase shift from 0 to π. Finally, due to the “MOR” effect, the spontaneously generated coherence related to the transition between the upper excited state and the ground state, allows for more precise control over the atom localization.

Thus, a three-dimensional localization is generated of a four-level double-λ type configuration with two doubly-degenerate ground and two upper excited states. To obtain the atomic localization points, left and right circularly polarized light are used simultaneously with a z-directed magnetic field and a linearly polarized weak probe field. In embodiments, such light can be experimentally produced by several methods, such as the photoexcitation of luminophores in glassy liquid crystals, a gas in a hollow-core waveguide. In embodiments, the method, systems, and/or devices described herein is based on a four-level double-λ type system, a closed loop under the magneto-optical rotation (“MOR”) condition. In embodiments, this specific configuration enables us to control the localization of the atoms via the induced spontaneously generated coherence as well as the magnetic field. Furthermore, the atomic localization can be inverted by switching the phase-shift from 0 to π. In embodiments, the precision on the localization is may be more sensitive to the left than the right susceptibility of the system which can be attributed to the coherence effect (that is between the ground and the excited state, compared to that of the ground and intermediate level).

Accordingly, atomic localization in a four-level atomic system via the left and the right circularly polarized light “MOR” effect is analyzed. In embodiments, the use of a magnetic field, induced spontaneously generated coherence (“SGC”), and dispersive standing wave fields (“DSWFs”) with phase shift demonstrates a high precision in localizing the atom. In embodiments, the “MOR” effect allows for a broad and flexible range of atomic control, for instance, the probability of localizing the atom is increased by a factor of 2 when the strength of the magnetic field increases. Furthermore, the dynamics of the atomic localization is fully controllable with phase shift via DSWFs which enables high precision in localizing the atom. Technically, the atomic position is inverted by switching the standing waves from in phase to out phase, resulting in a phase shift from 0 to π. Finally, due to the “MOR” effect, the spontaneously generated coherence related to the transition between the upper excited state and the ground state, allows for more precise control over the atom localization.

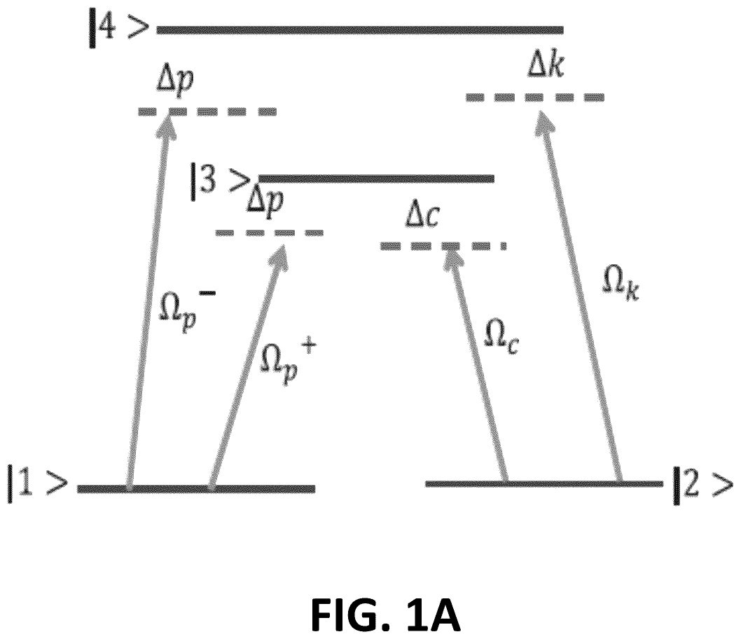

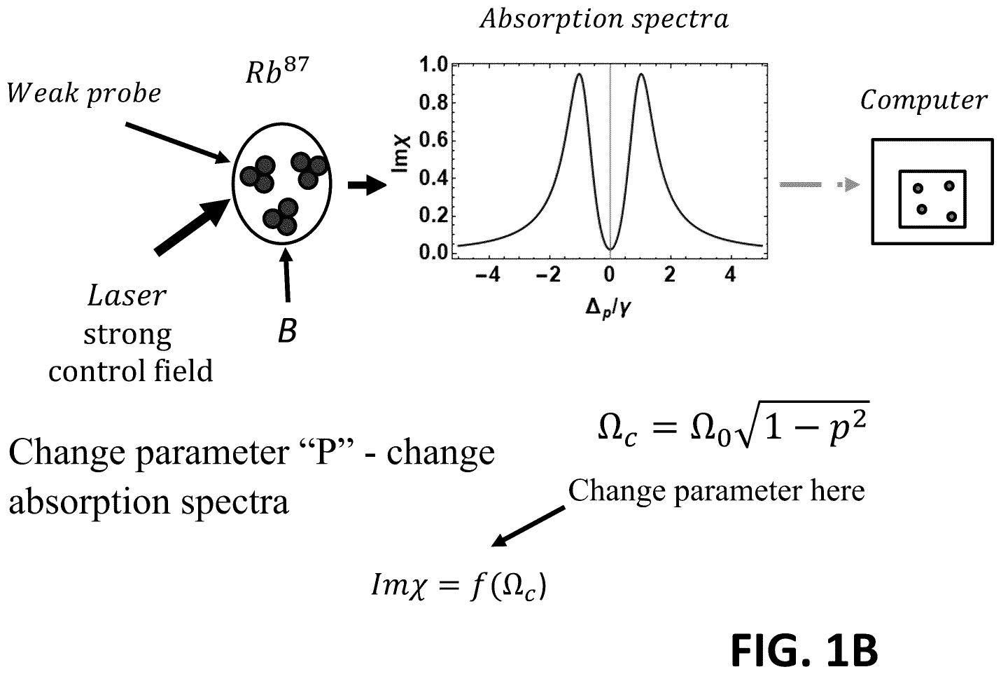

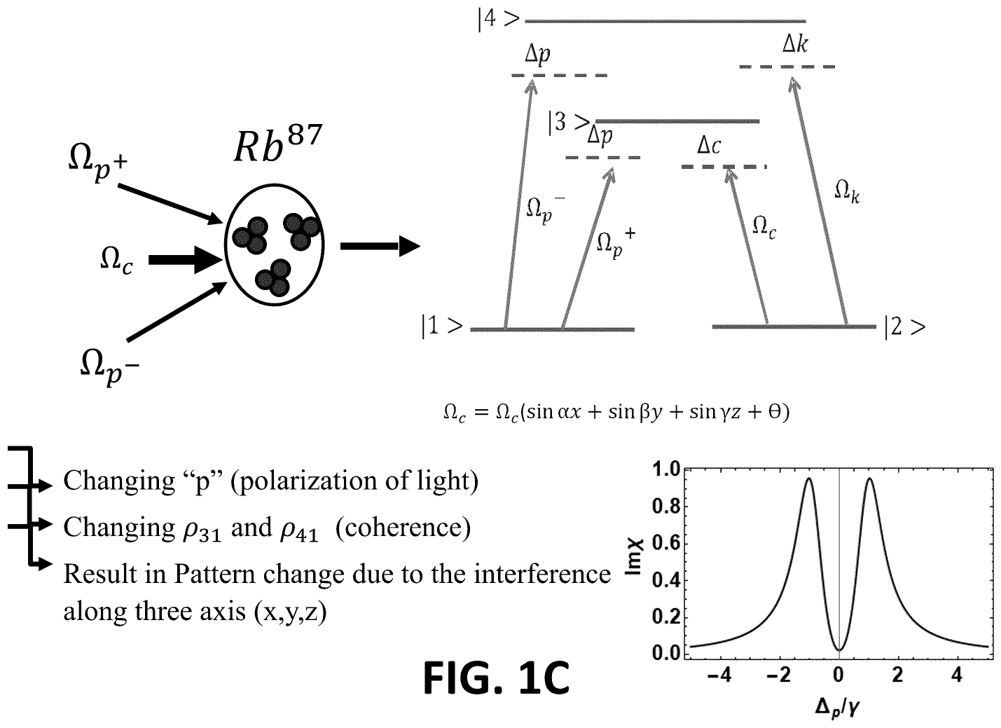

In embodiments, a four-level double-lambda type configuration with a probe light under magneto-optical rotation, is shown in FIG. 1A. In embodiments, the system is based on two doubly-degenerate ground states, given by |1, m=1> and |2, m=−1> and two higher levels |3, m=0> and |4, m=0>. In embodiments, the system can be experimentally realized with D2 lines of Rb⁸⁷ (Rubidium) atomic vapors (e.g., Rb⁸⁷ as shown in FIGS. 1B and 1C). In embodiments, the Rb atomic vapors may be generated by. The transitions occur between 52S(1/2)⇐⇒52P (3/2). The magnetic field (B^{→}=Bz\hat{ }) applied in the z-direction splits the energy level, i.e., ΔB=mₛgₛμ_{B}B/h. In addition, a weak linearly polarized probe field E^{→}=×Eₚe^{i(kpz-ωpt)}+c·c, is applied in parallel to the magnetic field (B^{→}=Bz\hat{ }) in the closed medium (e.g., Rb⁸⁷-rubidium atom vapors). While the systems, methods, and/or devices described herein use rubidium atom vapors (Rb⁸⁷), other elemental atom vapors may also be used. In embodiments, the applied linearly polarized probe field is based on the right and left circularly polarized lights. In embodiments, The circular components (respectively right and left), with Rabi frequency Ω⁺ₚ (Ω⁻ₚ), cause the transitions |3 [symbol] ⇐⇒|1 [symbol] (|4 [symbol] ⇐⇒|1 [symbol] ), where Ω⁺ₚ=E⁺ (( [symbol] )/h) and Ω⁺ₚ=E⁻(( [symbol] )/h). Ωₖ is applied between states |2 [symbol] and |4 [symbol] having Rabi oscillation Ωₖ=( [symbol] )/h Ek. E⁺=E⁻=Ep/√2, |μ₃₁|=|μ₄₁|. εᵢ (i=±, c) denotes the directional vectors of right/left circularly polarized lights and coupling field.

In embodiments, the splitting of Zeeman energy levels occurs in |3 [symbol] and |4 [symbol] and can be given by h ΔB=mₛgₛμ_{B}B, μ_{B} (gₛ) being the Bohr's magneton (Lande's factor) and mₛ=±1 is a quantum number (magnetic) of the respective sub-levels of excited states. The Hamiltonian in the interaction picture, and under the RWA with the electric dipole approximation, is given by equation (1) as:

$$H = - ℏ [ {Ω}_{p}^{-} {e}^{- i ( {Δ}_{p} + {Δ}_{B} ) t} \vert 4 〉 〈 1 \vert + {Ω}_{p}^{+} {e}^{- i ( {Δ}_{p} - {Δ}_{B} ) t} \vert 3 〉 〈 1 \vert + {Ω}_{c} {e}^{- i ( {Δ}_{p} - {Δ}_{B} ) t} \vert 3 〉 〈 2 \vert + {Ω}_{k} {e}^{- i ( {Δ}_{p} - {Δ}_{B} ) t} \vert 4 〉 〈 2 \vert ] + c c \qquad ( 1 )$$

In equation (1), cc indicates complex conjugate. Here we consider that Δₖ=Δ_{c}. The density matrix equations for the four-level atom are written in equation (2) as:

$$ρ = {\sum }_{k , l} {ρ}_{kl} {e}^{i ( {ω}_{k} - {ω}_{l} ) t} \vert k 〉 〈 l \vert \qquad ( 2 )$$

where k, l denote the levels 1 . . . 4 and ω_{k,l} are the corresponding frequencies. In terms of the basis set of the atom |1 [symbol] , |2 [symbol] , |3 [symbol] , and |4 [symbol] , we have equation (3) as:

$${Ψ}^{†} k {Ψ}_{1} = \vert k 〉 〈 l \vert and ρ = {ρ}_{kl} \vert k 〉 〈 l \vert \qquad ( 3 )$$

where Ψ^{†}, Ψ are the raising (lowering) operators for the corresponding decays. The time evolution of the density matrix is described by the Liouville Von Neumann equation given by:

$$\frac{d ρ}{dt} = - \frac{i}{ℏ} [ H , ρ ] , \qquad ( 4 )$$

The density matrix in our system is expressed as (Here we consider that Δₖ=Δ_{c}):

$$\dot{ρ} = - \frac{i}{ℏ} ⌊ H , ρ ⌋ - \frac{1}{2} {\sum }_{i , j} {γ}_{i , j} ( {Ψ}_{i}^{†} {Ψ}_{j} ρ + ρ {Ψ}_{i}^{†} {Ψ}_{j} - 2 {Ψ}_{i} {ρΨ}_{j}^{†} ) \qquad ( 5 )$$

Under the rotating wave approximation (neglecting the rapidly oscillating terms), the temporal dynamics of the system is given in terms of the atomic populations in the energetic levels (1,4) and the coherence (the off-diagonal elements) by:

$${\dot{ρ}}_{31} = ( i {Δ}_{p} - i {Δ}_{B} - {γ}_{31} ) {ρ}_{31} + i {Ω}_{ρ} + ( {ρ}_{11} - {ρ}_{33} ) + i {Ω}_{c} {ρ}_{21} - i {Ω}_{ρ} - {ρ}_{34} , \qquad ( 6 )$$

$${\dot{ρ}}_{21} = [ ( i {Δ}_{p} - i {Δ}_{c} ) - {γ}_{21} ] {ρ}_{21} + i {Ω}_{c} {ρ}_{31} + i {Ω}_{k} {ρ}_{41} - i {Ω}_{ρ} + {ρ}_{23} - i {Ω}_{ρ} - {ρ}_{24} ,$$

$${\dot{ρ}}_{41} = ( i {Δ}_{ρ} - i {Δ}_{B} - {γ}_{41} ) {ρ}_{41} + i {Ω}_{ρ} + ( {ρ}_{11} - {ρ}_{44} ) ) + i {Ω}_{k} {ρ}_{21} - i {Ω}_{ρ} - {ρ}_{43} ,$$

$${\dot{ρ}}_{11} = - {γ}_{11} {ρ}_{11} + i {Ω}_{ρ} + {ρ}_{31} + i {Ω}_{ρ} + {ρ}_{41} - i {Ω}_{ρ} + {ρ}_{13} - i {Ω}_{ρ} - {ρ}_{14} ,$$

$${\dot{ρ}}_{32} = ( i ( {Δ}_{c} + {Δ}_{B} ) - {γ}_{23} ) {ρ}_{32} - i {Ω}_{c} {ρ}_{33} - i {Ω}_{k} {ρ}_{34} + i {Ω}_{ρ} + {ρ}_{12} + i {Ω}_{c} {ρ}_{22} ,$$

$${\dot{ρ}}_{33} = - {γ}_{33} {ρ}_{33} + i {Ω}_{ρ} + {ρ}_{13} + i {Ω}_{c} {ρ}_{23} - i {Ω}_{ρ} + {ρ}_{31} i {Ω}_{c} {ρ}_{32} ,$$

$${\dot{ρ}}_{42} = ( i ( {Δ}_{c} + {Δ}_{B} ) - {γ}_{24} ) {ρ}_{42} - i {Ω}_{c} {ρ}_{43} - i {Ω}_{k} ( {ρ}_{44} - {ρ}_{22} ) + i {Ω}_{ρ} - {ρ}_{21} ,$$

$${\dot{ρ}}_{43} = - {γ}_{34} {ρ}_{43} - i {Ω}_{ρ} + {ρ}_{41} - i {Ω}_{c} {ρ}_{42} + i {Ω}_{ρ} + {ρ}_{13} + i {Ω}_{k} {ρ}_{23} ,$$

$${\dot{ρ}}_{44} = - {γ}_{44} {ρ}_{44} + i {Ω}_{ρ} - {ρ}_{14} + i {Ω}_{k} {ρ}_{24} - i {Ω}_{ρ} - {ρ}_{41} - i {Ω}_{k} {ρ}_{42} .$$

As shown in the set of formulas for equation (6) γ₃₁(γ₄₁) is the decay rate of the excited levels |1 [symbol] −→|3 [symbol] (|1 [symbol] −→|4 [symbol] ). The control field under the spontaneously generated coherence “SGC” effect is written as:

$${Ω}_{c} = {Ω}_{0} \sqrt{1 - {p}^{2}} \qquad ( 7 )$$

Where p denotes the SGC parameter and defines the quantum coherence that results from various spontaneous emission pathways. The strength of p depends on the dipole moments' alignment μ13 and μ14 and is given by

$$p = {μ}_{13} \cdot {μ}_{14} \vert = cos η , \vert {μ}_{13} \cdot {μ}_{14} \vert \qquad ( 8 )$$

where η is the angle between the dipoles. The coherence parameter p arises when the transition occurs between two emission channels |3 [symbol] ↔|1 [symbol] and |4 [symbol] ↔|1 [symbol] . For orthogonal dipole moments, p=0, no quantum interference occurs. For the case of p=1, the maximum quantum interference occurs since the dipole moments are parallel. (Ec) is used to control the angle n and it is defined as:

$${Ω}_{c} = {Ω}_{1} sin η = {Ω}_{1} \sqrt{1 - {p}^{2}} \qquad ( 9 )$$

We consider the control field as three-dimensional standing wave field written as:

$${Ω}_{c} = {Ω}^{0} ( sin kx + sin ky + sin ( kz + θ ) ) \qquad ( 10 )$$

$$= {Ω}_{c} ( x ) + {Ω}_{c} ( y ) + {Ω}_{c} ( z ) \qquad ( 11 )$$

Thus, as shown, equation (11) equals equation (10). The wave vector for each standing-wave field is given by k=2π/λ, and λ is the wavelength of the corresponding standing-wave field. The parameters θ is the phase shifts associated with the standing-wave fields with wave vector kz=k. The polarization of the medium due to the right circularly polarized light Ep+ is:

$${P}^{+} = χϵ {oEp}^{+} , \qquad ( 12 )$$

While the left-handed response of the medium due to the probe electric field Ep− is:

$${P}^{-} = {χϵ}_{o} {E}_{{p}^{-}} , \qquad ( 13 )$$

additionally, P⁺=2Nμ₃₁ρ₃₁ and P⁻=2Nμ₄₁ρ₄₁. On the other hand, the left and right-handed susceptibilities (χ⁺ and χ⁻) are related to the medium coherence as:

$${χ}^{+} = \frac{2 N {\vert {μ}_{31} \vert}^{2} {ρ}_{31}}{{Ω}_{p} h {ϵ}_{o}} \qquad ( 14 )$$

$${χ}^{-} = \frac{2 N {\vert {μ}_{41} \vert}^{2} {ρ}_{41}}{{Ω}_{p} h {ϵ}_{o}} \qquad ( 15 )$$

In embodiments, N represents atomic density number, μ₃₁ and μ₄₁ are the dipoles. The solutions of the density matrix are given in the Appendix. The imaginary part of the complex susceptibility which gives the coefficient of the spatially modulated absorption in the standing-wave regime, can be written as a function of the position distribution of the atomic absorption. Therefore, we note that;

$$Im ( {χ}^{+} ) = f ( {Ω}_{c} ) = {A}_{0} f ( x , y , z ) \qquad ( 16 )$$

$$Im ( {χ}^{-} ) = g ( {Ω}_{c} ) = {A}_{0} g ( x , y , z ) \qquad ( 17 )$$

where A0=(2Nμ²₁₂)/hγ. Thus the imaginary χ is related to a function f(x,y,z) and likewise χ− is proportional to a function g(x,y,z). In embodiments, the center-of-mass of the atom position is assumed to be constant along the directions of the standing waves and thus it is also considered that the kinetic energy of the atom is neglected, this is known as the Raman-Nath approximation.

In embodiments, the three-dimensional localization of the atoms is then analyzed. In embodiments, the atom localization structure is obtained in the 3D domain (−π≤kx, ky, kz≤2π) assuming that k=λ. In embodiments, the atom is localized at the position corresponding to a maxima of the filter function (by taking the imaginary part of the susceptibility): gmax and fmax due to the MOR effect. In embodiments, the effect of the induced generated coherence under the MOR effect as well as the effect of the magnetic field is analyzed. Furthermore, the dispersive standing wave fields with phase shift under the SGC is analyzed. Finally, the quantum control of the atomic localization with the phase shift is also analyzed.

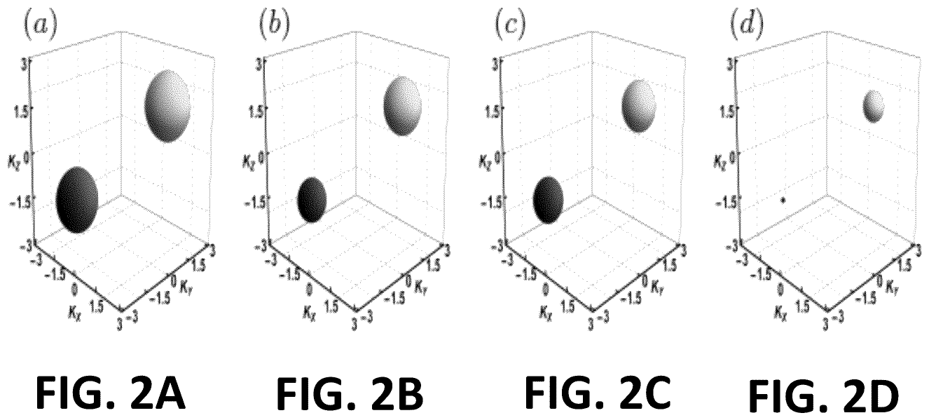

FIG. 1B further describes the manipulation of the angle of polarization between the input lights, to generate an SGC effect, as described above. In embodiments, since the wave is a three dimensional (3D) standing wave, the 3D absorption spectrum of the atom (Im of susceptibility) can also be manipulated. In embodiments, a wave generator (with lasers) creates two waves in opposite directions. In embodiments, the combination of the two waves (from interference) creates a standing wave (e.g., a 3-D wave). In embodiments, the wave generator may include one or more antennas, lasers, polarizers, and mirrors (to focus the light). In embodiments, the output of the manipulation of the waves may be sent to a spectrograph which can generate an absorption spectrum as shown in FIG. 1B. In embodiments, the output of the absorption spectrum may be sent to a computing device (such as computing device 900). In embodiments, computing device 900 may have software that generates three dimensional graphical outputs as shown in FIGS. 2A-2D, 3A-3D, 4A-4D, 5A-5D, 6A-6D, and 7A-7D based on various manipulations of different features. In embodiments, such graphical displays generated by computing device 900 describe the measurement of coherence. In embodiments, as the input wave is a 3D (depends on x, y and z), the generated effect (wave pattern shown on a spectrograph) is also 3D; and, thus, the imaginary of the susceptibility gives the information about the atom localization. Accordingly, a better atom localization is determined by manipulating the SCG effect.

As shown in FIG. 1B, the dipole moment angle is created between the left and right circularly polarized light (via the use of the strong control laser, i.e., the strong control field), a z-directed magnetic field (“B” as shown in FIG. 1B), and a linearly polarized weak probe field (weak probe). Hence, we derive the left and right magneto-optical susceptibilities induced by the quantum coherence in the atomic system. This provides control of the 3D-atomic localization through the induced spontaneously generated coherence (“SGC”), the optical and magnetic fields, and the phase shift. As shown in FIG. 1B, this manipulation (e.g., the manipulation of the polarization of the light, “P,” results in a change in coherence which results in a pattern change due to the interference of the laser strong control field, the magnetic field, and the weak probe) results in an output absorption spectra which is then sent to a computing device to generate additional graphical features.

FIG. 1C shows a three-dimensional localization is generated of a four-level double-λ type configuration with two doubly-degenerate ground and two upper excited states (which is described in FIG. 1A). As shown in FIG. 1C, a weak linearly polarized probe field [symbol] =xEp e^{i(kpz-ωpt)}+c·c, is applied in parallel to the magnetic field (B^{→}=Bz\hat{ }) in the closed medium (Rb⁸⁷). In embodiments, the application of the weak linearly polarized field E and magnetic field B results in Ω_{c}=Ω₀\sqrt{1−p²} (as described above) to a linearly polarized probe field, that is based on the right and left circularly polarized lights (Ω⁺ and Ω⁻). In embodiments, the weak linearly polarized probe field E and the magnetic field B may be generated by an external laser source (e.g. a polarizer) that generates the electric and magnetic field. In embodiments, the polarizer may include mirrors that can be manipulated through the adjustment of phases to split the waves and hence to manipulate the angle. In embodiments, as already described above, the applied linearly polarized probe field is based on the right and left circularly polarized lights. In embodiments, the circular components (respectively right and left), with Rabi frequency Ω+ (Ω−) cause the transitions |3 [symbol] ⇐⇒|1 [symbol] (|4 [symbol] ⇐⇒|1 [symbol] where Ω+=E+(( [symbol] ·ϵ\hat{ }+)) and Ω−=E−(( [symbol] ·ϵ\hat{ }−)). Ωk is applied between Ω+p=E+((μ31·ϵ+)/h), Ep states |2 [symbol] and |4 [symbol] having Rabi oscillation Ωk=Ek((μ31·ϵ+)/h) E+=E−=Ep/√2. |μ₃₁|=|μ₄₁|. ϵi(i=±, c) denotes the directional vectors of right/left circularly polarized lights and coupling field.

FIG. 2A-2D describe the isosurface plots for the atomic localization under the effect of the magnetic field (which is proportional to the magnetic detuning). First, p=0, (no effect of the spontaneously generated coherence. Two cases are considered: Δ_{B}=3.5 (FIGS. 2A and 2B) and Δ_{B}=4.0 (FIGS. 2C and 2D). In embodiments, ϕ in FIGS. 2A-2D is the relative phase while the wave is assumed to be monochromatic with no phase shift. In embodiments, the isosurfaces are reported by taking Im (χ+) (representing the susceptibility due to the right circularly polarized light) in FIGS. 2A and 2C. Those obtained by taking Im (χ−) (representing the susceptibility due to the left circularly polarized light) are shown in FIGS. 2B and 2D. In embodiments, the atomic localization is sensitive to the change of the strengths of ΔB. As seen in FIGS. 2A and 2B, the atomic localization has a larger probability compared to that found in FIGS. 2C and 2D.

Indeed, while increasing Δ_{B} affects the left- and right-handed susceptibilities, the exact localization points of the atoms do not change with Δ_{B}, the coordinates of the localization remain the same. For example, in FIG. 2A, the center of mass of the blue isosurface is located at −1.5, −0.5, −2 approximately which is the same in FIG. 2C. Besides, the atomic localization shape shrinks for higher values of ΔB (FIGS. 2C and 2D). Thus, a better precision of the atomic localization by increasing the magnetic field detuning is determined. In embodiments, the Left-handed susceptibility due to the left circularly polarized light has better precise control on the localization of the atoms.

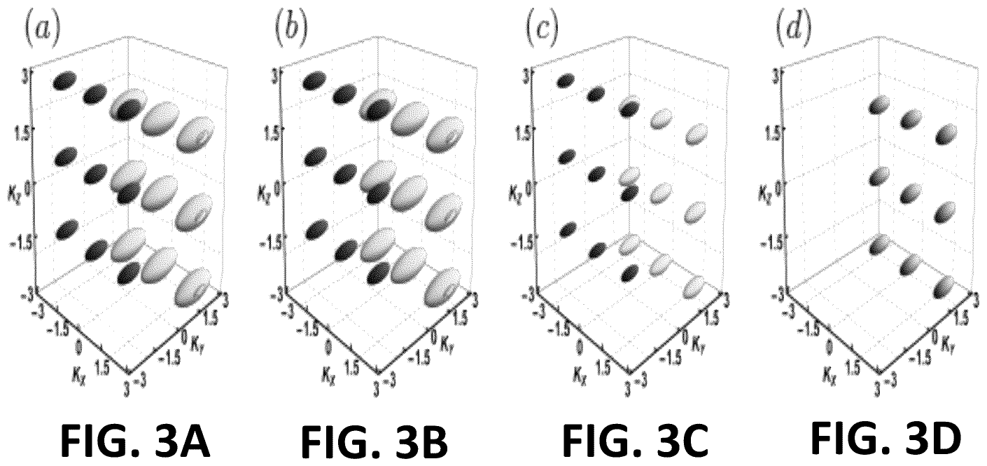

In embodiments, the effect of the SGC due to the left and right circularly polarized light is analyzed. It is worth noting here, that the SGC in the case of the atomic configuration is induced due to the quantum interference. FIG. 3 describes the left- and right-handed susceptibilities for two different values of the SGC parameter p=0.7 (FIGS. 3A and 3B) and p=0.8 (FIGS. 3C and 3D). Compared to FIG. 2, we get oval shapes when the χ+ and χ− functions are under the effect of the induced SGC. Therefore, the atomic localization are altered by the SGC values. In embodiments, the atom's localization is enhanced for p=0.7 in comparison to p=0. By increasing p to 0.8, the probability for precisely localizing the atom increases by a factor of 2 (as shown in FIGS. 3C and 3D). Additionally, the atomic localization shapes vary drastically against the increase of Kx and Ky. For example, a better precision in the oval shapes around Ky=1.5 are observed. On another point, when the SGC is p=0.8, the shapes tend to shrink.

Similarly to the case of the magnetic field effect, it is clear that the Left-handed susceptibility due to the left circularly polarized light has better precise control on the localization of the atoms, due to the induced spontaneously generated coherence. In embodiments, this effect is explained by the magneto optical effect on the transition 4,1 since it is related to the absorption of the atom between the upper excited state and the ground state. In contrast, the right susceptibility is influenced by the magneto optical effect between states 1 and 3, where the state 3 is an intermediate transition (less stable).

In order to get deeper insights on the atomic localization while keeping a flexible control of the system, we investigate the effect of the SGC while the standing wave is dispersive, thus the field Ωc is the superposition of three standing waves such as:

$${Ω}_{c} = {Ω}_{o}^{c} ( sin α x + sin β y + sin ( γ z + θ ) ) \qquad ( 18 )$$

θ is the phase shift, α, β, γ are different and respectively proportional to 2π/λ1, 2π/λ2 and, 2π/λ3.

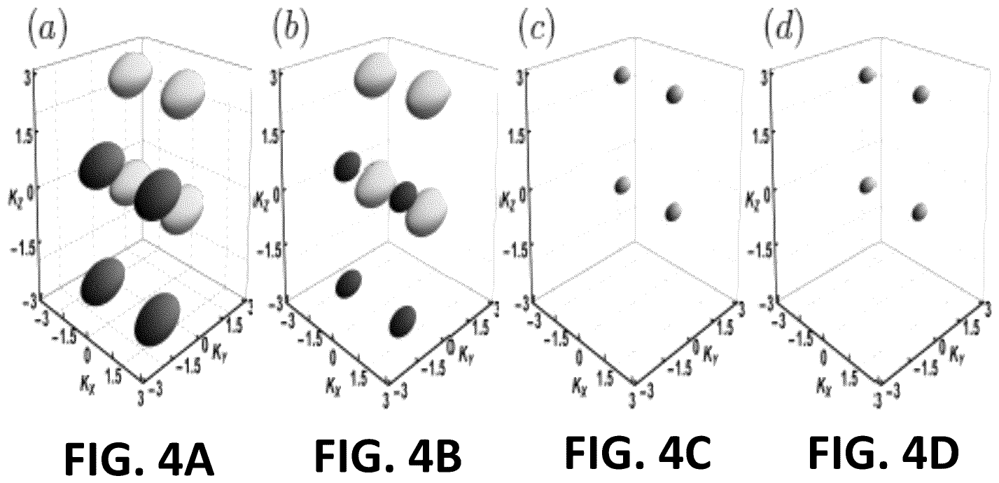

Hence, as shown in FIG. 4, w the atomic localization for a dispersive standing wave is shown under the induced spontaneously generated coherence where we take p=0.7 in FIGS. 4A and 4B) and p=0.82 in FIGS. 4C and 4D. The wave numbers α, β, γ are considered respectively as 2, 1, 2. By increasing the SGC, we clearly get distinct results from the case (a, and b). In (a, and b) we have larger isosurfaces (with probability distributed along the 3D axis). Increasing the SGC leads to less points and higher precisions (smaller volumes of the spheres). Besides, if we look at FIG. 3 and compare it to the case of FIGS. 4A-4D where the standing wave is considered dispersive, we notice that, we get less isosurfaces (in number).

In embodiments, the obtained high precision to the interaction mechanism between the three different standing waves and their nodes/antinodes superposition process. In embodiments, dispersive waves have, in general, variable wave modes, frequency, wave number, phase speed and energy leading to various ways of waves interactions. In other terms, with three waves with three different wave number and hence three different wavelength λ₁, λ₂, λ₃, one can get better space topography since we localize the atom within the intersection of the space period:

$$- π \leq \frac{2 π}{{λ}_{1}} x \leq π$$

$$and , - π \leq \frac{2 π}{{λ}_{2}} y \leq π$$

$$and , - π \leq \frac{2 π}{{λ}_{3}} z \leq π$$

thus within the three regions of the different waves, a better precision is obtained. Finally, the left χ⁻ strongly affects the precision and resolution of the 3D atomic localization under the dispersive standing wave fields “DSWFs”.

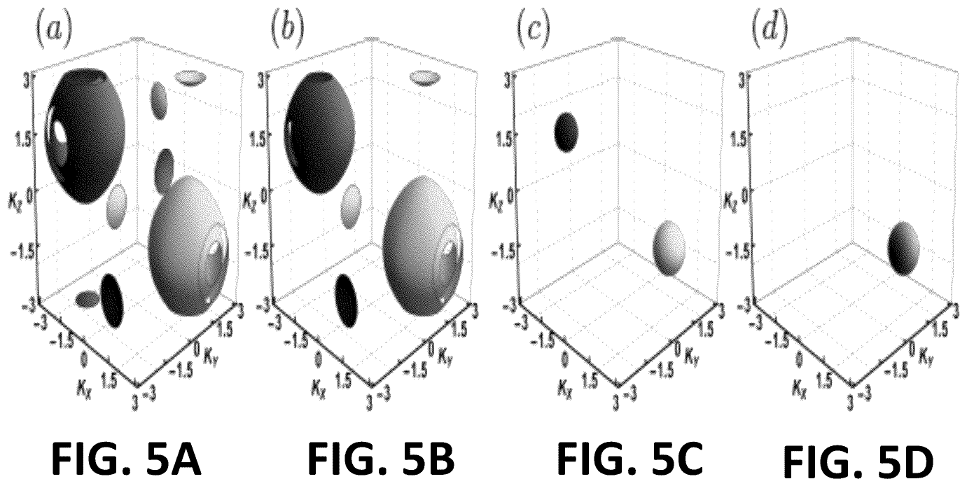

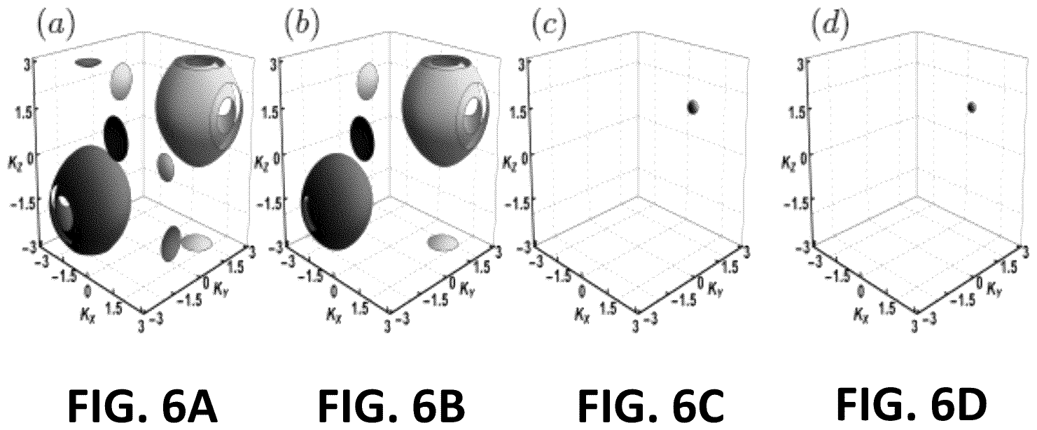

As shown in FIG. 5A-5D, the atomic localization of the right and left susceptibilities with phase shift (θ=π). Hence, in FIGS. 5A and 5B, the SGC is zero, while in (c) and (d), we introduce the SGC effect. As shown in FIGS. 5A and 5B, the isosurfaces have low resolution and thus cannot provide precise localization for the atom. However, by using the SGC, the surfaces shrink and high precision is achieved. Likewise, as shown in FIG. 6A-6D, the dynamics of the Left-handed susceptibility and Right-handed susceptibility for the atomic localization for a phase shift θ=0 are shown. In embodiments, the standing wave fields are in phase, a better coherence is generated thus a high precise localization is obtained. We also notice that the localization of the spheres is opposite to that described in FIGS. 5A-5D.

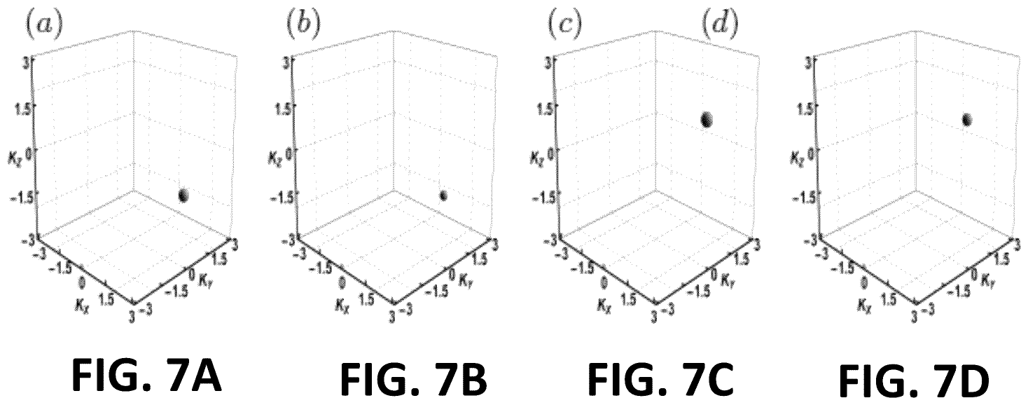

Hence, by switching the phase from π to 0, we invert the atomic localization. Additionally, as stated earlier in the previous figures, the SGC induces a high precision in the localization. In embodiments, the left susceptibility is more sensitive to the effect of the SGC since it is related to the probe absorption transition. By manipulating the phase shift (as shown in FIGS. 7A and 7B), the phase difference between the standing wave fields is set to Π/8 while in FIGS. 7C and 7D it is set to π). In embodiments, a very high precise localization of the atom is determined but also a shift in the position. The position of the atom is first localized at (0,3,−2) with a θ=π/8, by changing θ=π the localization of the atoms is shifted to (0,3,0).

In embodiments, the three-dimensional localization of a four-level double-A type configuration with two doubly-degenerate ground and two upper excited States. The atomic localization points are obtained by manipulating the dipole moment angle between the left and right circularly polarized light, a z-directed magnetic field, and a linearly polarized weak probe field. Hence, we derive the left and right magneto-optical susceptibilities induced by the quantum coherence in the atomic system. This provides control the 3D-atomic localization through the induced spontaneously generated coherence (“SGC”), the optical and magnetic fields, and the phase shift. Finally, tailoring the quantum coherence for atom localization through the manipulation of the external applied fields opens the gate to a wide range of applications such as quantum logic gates processing, quantum computing, and quantum error reduction.

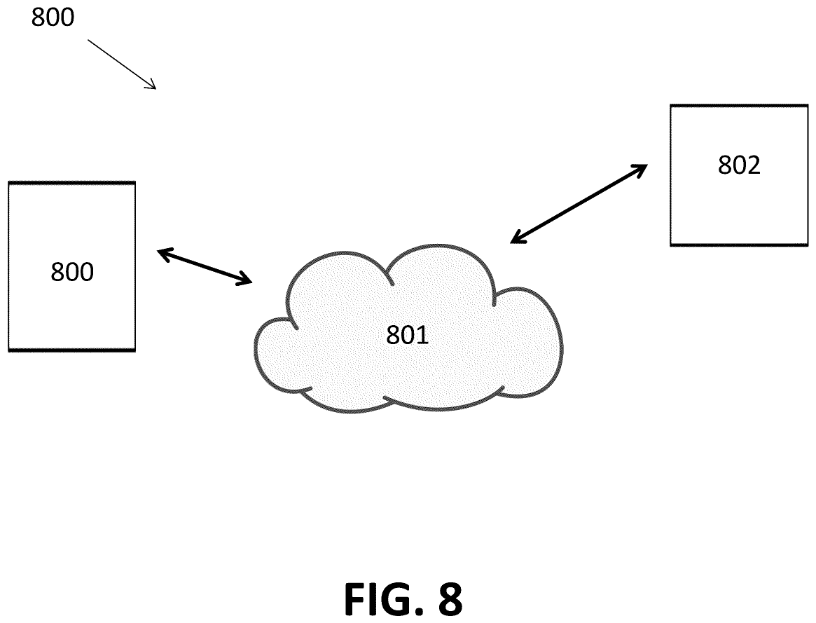

FIG. 8 is a diagram of example environment 800 in which systems, devices, and/or methods described herein may be implemented. FIG. 8 shows network 801, apparatus 800, and database 802. Network 801 may include a local area network (LAN), wide area network (WAN), a metropolitan network (MAN), a telephone network (e.g., the Public Switched Telephone Network (PSTN)), a Wireless Local Area Networking (WLAN), a WiFi, a hotspot, a Light fidelity (LiFi), a Worldwide Interoperability for Microware Access (WiMax), an ad hoc network, an intranet, the Internet, a satellite network, a GPS network, a fiber optic-based network, and/or combination of these or other types of networks.

Additionally, or alternatively, network 801 may include a cellular network, a public land mobile network (PLMN), a second generation (2G) network, a third generation (3G) network, a fourth generation (4G) network, a fifth generation (5G) network, and/or another network. In embodiments, network 822 may allow for devices describe in any of the figures to electronically communicate (e.g., using emails, electronic signals, URL links, web links, electronic bits, fiber optic signals, wireless signals, wired signals, etc.) with each other so as to send and receive various types of electronic communications. In embodiments, network 801 may include a cloud network system that incorporates one or more cloud computing systems.

Apparatus 800 may include any computation or communications device that is capable of communicating with a network (e.g., network 801). Apparatus 800 is described in FIG. 8 and may include additional features described herein. For example, apparatus 800 may include a radiotelephone, a personal communications system (PCS) terminal (e.g., that may combine a cellular radiotelephone with data processing and data communications capabilities), a personal digital assistant (PDA) (e.g., that can include a radiotelephone, a pager, Internet/intranet access, etc.), a smart phone, a desktop computer, a laptop computer, a tablet computer, a camera, a personal gaming system, a television, a set top box, a digital video recorder (DVR), a digital audio recorder (DUR), a digital watch, a digital glass, or another type of computation or communications device.

Apparatus 800 may receive and/or display electronic content. In embodiments, the electronic content may include objects, data, images, audio, video, text, files, and/or links to files accessible via one or more networks. Content may include a media stream, which may refer to a stream of electronic content that includes video content (e.g., a video stream), audio content (e.g., an audio stream), and/or textual content (e.g., a textual stream). In embodiments, an electronic application may use an electronic graphical user interface to display content and/or information via apparatus 100. Apparatus 800 may have a touch screen and/or a keyboard that allows a user to electronically interact with an electronic application or a webpage (either containing electronic content). In embodiments, apparatus 800 may be used to generate one or more graphs and analysis as described in FIGS. 1-7.

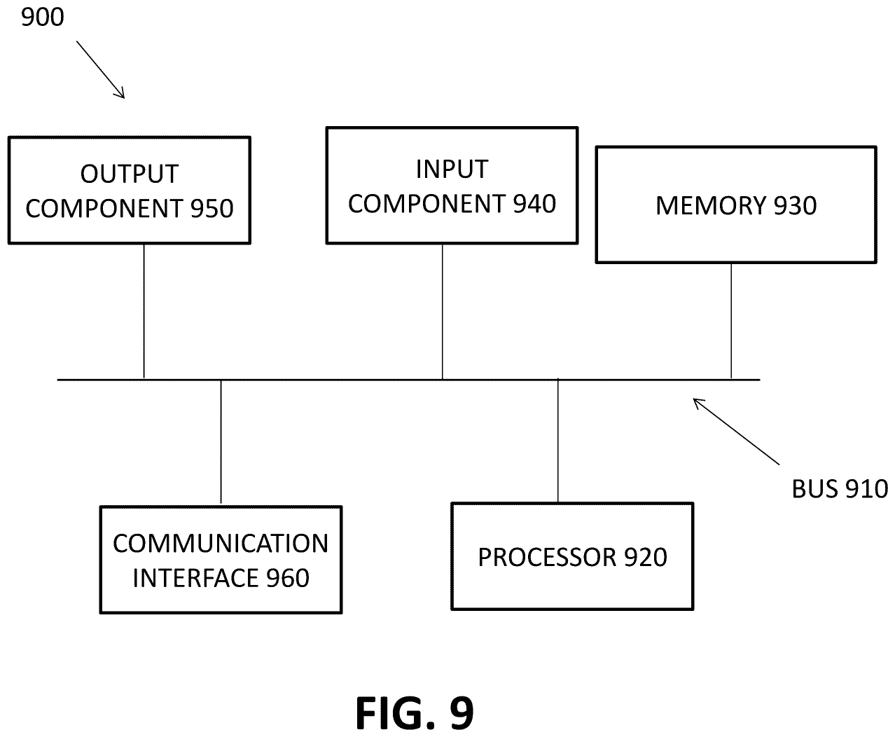

FIG. 9 is a diagram of example components of a device 900. Device 900 may correspond to network 801, apparatus 800, and computing system 814. Alternatively, or additionally, network 801, apparatus 800, computing system 814, and/or database 802 may include one or more devices 900 and/or one or more components of device 900.

As shown in FIG. 9, device 900 may include a bus 910, a processor 920, a memory 930, an input component 340, an output component 950, and a communications interface 360. In other implementations, device 900 may contain fewer components, additional components, different components, or differently arranged components than depicted in FIG. 9. Additionally, or alternatively, one or more components of device 900 may perform one or more tasks described as being performed by one or more other components of device 900.

Bus 910 may include a path that permits communications among the components of device 900. Processor 920 may include one or more processors, microprocessors, or processing logic (e.g., a field programmable gate array (FPGA) or an application specific integrated circuit (ASIC)) that interprets and executes instructions. Memory 930 may include any type of dynamic storage device that stores information and instructions, for execution by processor 920, and/or any type of non-volatile storage device that stores information for use by processor 920. Input component 940 may include a mechanism that permits a user to input information to device 800, such as a keyboard, a keypad, a button, a switch, voice command, etc. Output component 950 may include a mechanism that outputs information to the user, such as a display, a speaker, one or more light emitting diodes (LEDs), etc.

Communications interface 960 may include any transceiver-like mechanism that enables device 900 to communicate with other devices and/or systems. For example, communications interface 960 may include an Ethernet interface, an optical interface, a coaxial interface, a wireless interface, or the like. In another implementation, communications interface 960 may include, for example, a transmitter that may convert baseband signals from processor 920 to radio frequency (RF) signals and/or a receiver that may convert RF signals to baseband signals. Alternatively, communications interface 960 may include a transceiver to perform functions of both a transmitter and a receiver of wireless communications (e.g., radio frequency, infrared, visual optics, etc.), wired communications (e.g., conductive wire, twisted pair cable, coaxial cable, transmission line, fiber optic cable, waveguide, etc.), or a combination of wireless and wired communications.

Communications interface 960 may connect to an antenna assembly (not shown in FIG. 9) for transmission and/or reception of the RF signals. The antenna assembly may include one or more antennas to transmit and/or receive RF signals over the air. The antenna assembly may, for example, receive RF signals from communications interface 960 and transmit the RF signals over the air, and receive RF signals over the air and provide the RF signals to communications interface 960. In one implementation, for example, communications interface 960 may communicate with network 201.

As will be described in detail below, device 900 may perform certain operations. Device 900 may perform these operations in response to processor 920 executing software instructions (e.g., computer program(s)) contained in a computer-readable medium, such as memory 330, a secondary storage device (e.g., hard disk.), or other forms of RAM or ROM. A computer-readable medium may be defined as a non-transitory memory device. A memory device may include space within a single physical memory device or spread across multiple physical memory devices. The software instructions may be read into memory 930 from another computer-readable medium or from another device. The software instructions contained in memory 930 may cause processor 920 to perform processes described herein. Alternatively, hardwired circuitry may be used in place of or in combination with software instructions to implement processes described herein. Thus, implementations described herein are not limited to any specific combination of hardware circuitry and software.

The above-described examples may be implemented in many different forms of software, firmware, and hardware in the implementations illustrated in the figures. In embodiments, the actual software code or specialized control hardware used to implement these aspects should not be construed as limiting. Thus, the operation and behavior of the aspects were described without reference to the specific software code—it being understood that software and control hardware could be designed to implement the aspects based on the description herein.

Even though particular combinations of features are recited in the claims and/or disclosed in the specification, these combinations are not intended to limit the disclosure of the possible implementations. In fact, many of these features may be combined in ways not specifically recited in the claims and/or disclosed in the specification. Although each dependent claim listed below may directly depend on only one other claim, the disclosure of the possible implementations includes each dependent claim in combination with every other claim in the claim set.

While various actions are described as selecting, displaying, transferring, sending, receiving, generating, notifying, and storing, it will be understood that these example actions are occurring within an electronic computing and/or electronic networking environment and may require one or more computing devices, as described in FIG. 2, to complete such actions.

No element, act, or instruction used in the present application should be construed as critical or essential unless explicitly described as such. Also, as used herein, the article “a” is intended to include one or more items and may be used interchangeably with “one or more.” Where only one item is intended, the term “one” or similar language is used. Further, the phrase “based on” is intended to mean “based, at least in part, on” unless explicitly stated otherwise.

In the preceding specification, various preferred embodiments have been described with reference to the accompanying drawings. It will, however, be evident that various modifications and changes may be made thereto, and additional embodiments may be implemented, without departing from the broader scope of the invention as set forth in the claims that follow. The specification and drawings are accordingly to be regarded in an illustrative rather than restrictive sense.

What is claimed is:

1. A method, for atomic localization in a four-level atomic system, comprising:
generating, by a laser system, a magnetic field and a linearly polarized weak probe field, wherein the magnetic field and the linearly polarized weak probe field are generated by a polarizer that is part of the laser system;
generating, by the laser system, a laser strong control field;
applying the magnetic field, the linearly polarized weak probe, and the laser strong control field to atomic vapors;
generating an SGC effect to the atomic vapors based on an interference created by the applying the magnetic field, the linearly polarized weak probe, and the laser strong control field to atomic vapors; and
determining atom locations based on generating the SGC effect; and
generating an electronic graph showing the atom locations.

2. The method of claim 1, wherein the electronic graph is a three-dimensional graph.

3. The method of claim 1, wherein the electronic graph is generated based on an absorption spectra.
